(19) United States
(12) Patent Application Publication
(10) Pub. No.: US 2016/0161854 A1
(43) Pub. Date: Jun. 9, 2016

(54) STAGES, LITHOGRAPHY APPARATUS, AND METHOD OF MANUFACTURING DEVICES

(71) Applicant: CANON KABUSHIKI KAISHA, Tokyo (JP)

(72) Inventor: Tomohiro Harayama, Utsunomiya-shi (JP)

(21) Appl. No.: 14/958,291

(22) Filed: Dec. 3, 2015

(30) Foreign Application Priority Data
Dec. 8, 2014 (JP) 2014-247721

(51) Int. Cl. G03F 7/20

(52) U.S. Cl. CPC G03F 7/707

(57) ABSTRACT

A stage apparatus includes a moving part and chuck. The moving part can hold a substrate and move. The chuck has a holding surface divided into regions whose holding strength can be regulated individually. Some parts of the divided regions hold a part of the substrate. The moving part and the chuck are physically isolated.

### BACKGROUND OF THE INVENTION

1. Field of the Invention

The present invention relates to stages, lithography apparatus, and methods of manufacturing devices.

2. Description of the Related Art

Lithography apparatus (imprint apparatus or exposure apparatus) to manufacture semiconductor devices has movable stages holding substrates (wafers). For example, imprint apparatus transfers patterns on templates to substrates by pressing the templates to UV-curable resist on the substrates held on stages, solidifying the resist, and separating the solidified resist from the substrates. During the separation, the patterns can be damaged, peeled off the substrates or turn off themselves. With regard to this, Japanese Patent Laid-Open No. 2010-098310 and Japanese Patent Laid-Open No. 2007-219537 disclose imprint apparatus with stages which have many divided substrate holding regions. The holding strength of each holding region is regulated respectively.

The stage of Japanese Patent Laid-Open No. 2010-098310 and Japanese Patent Laid-Open No. 2007-219537 has a wafer holding part called chuck on it. For the stage system, if the chuck is divided into regions, a lot of pipes and related parts will have to be mounted on the moving part of the stage, which results in complexity and large footprint of the stage. It also causes weight gain of the stage and disturbs the fast movement of the stage and therefore its throughput.

### SUMMARY OF THE INVENTION

The present invention provides stages which improve pattern defects and fast movement of the stages and therefore their throughput.

The present invention has a stage which includes a moving part and chuck. The moving part can hold a substrate and move. The chuck has a holding surface divided into regions whose holding strength can be regulated individually. Some parts of the divided regions hold a part of the substrate. The moving part and the chuck are physically isolated.

Further features of the present invention will become apparent from the following description of exemplary embodiments (with reference to the attached drawings).

### BRIEF DESCRIPTION OF THE DRAWINGS

FIG. 1 is a side view drawing a configuration of imprint apparatus according to the first embodiment.

FIG. 2 is the top view of FIG. 1.

FIG. 3 is a sketch of the divided regions of the holding surface of the chuck according to the second embodiment.

FIG. 4A is a sketch specifying a center portion of a substrate to be imprinted.

FIG. 4B is the same sketch as FIG. 4A making the substrate and the chuck overlap.

FIG. 5A is a sketch specifying a left edge portion of a substrate to be imprinted.

FIG. 5B is the same sketch as FIG. 5A making the substrate and the chuck overlap.

FIG. 6A is a sketch specifying an upper left edge portion of a substrate to be imprinted.

FIG. 6B is the same sketch as FIG. 6A making the substrate and the chuck overlap.

### DESCRIPTION OF THE EMBODIMENTS

Hereinafter, modes for carrying out the present invention will be described with reference to the drawings, etc.

### First Embodiment

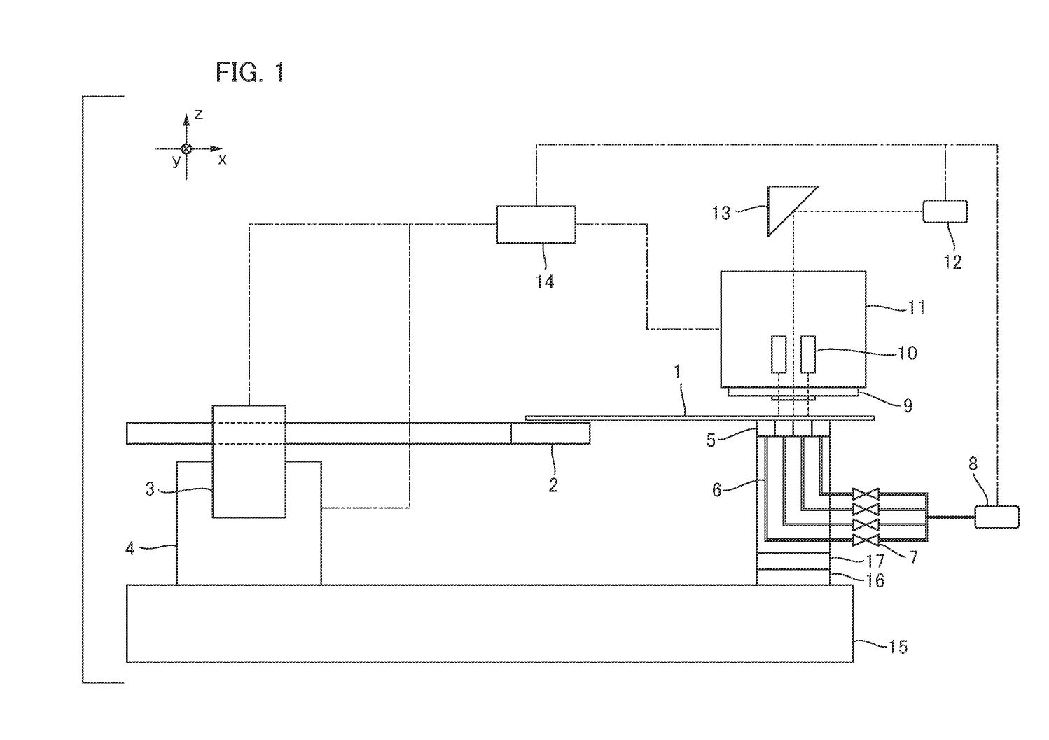

FIG. 1 is a side view drawing a configuration of imprint apparatus according to the first embodiment of the present invention which can be applied to a stage. The imprint apparatus uses liquid resist as imprint material which is solidified with UV exposure. However, the imprint apparatus can be other types that use heat or other energy instead of UV exposure. The imprint apparatus illustrated in FIG. 1 includes a stage holding a substrate 1, an imprint head 11 holding a template 9 which can move in Z-axis perpendicular to the substrate, an alignment scope 10, and an ultraviolet irradiation mechanism 12. The stage has a moving part 2 holding the substrate 1 and a chuck chucking a part of the substrate 1. The moving part 2 and the chuck are configured to be physically separated and each of them is supported independently on a base plate 15. The moving part 2 is attached to an x-axis and a y-axis actuators 3 and 4 respectively, and is moved on the xy-plane parallel to the surface of the substrate 1. During the movement, the substrate 1 is held on a part of it by a holding means (not illustrated) of the moving part 2. The chuck has a chucking part 5 with a holding surface, vacuum lines 6, and electromagnetic valves 7. The chucking strength of the chucking part 5 can be controlled by a chuck control unit 8. In addition, the chucking part 5 is also attached to an x-axis and a y-axis fine actuators 16 and 17 respectively, and can be moved on the xy-plane.

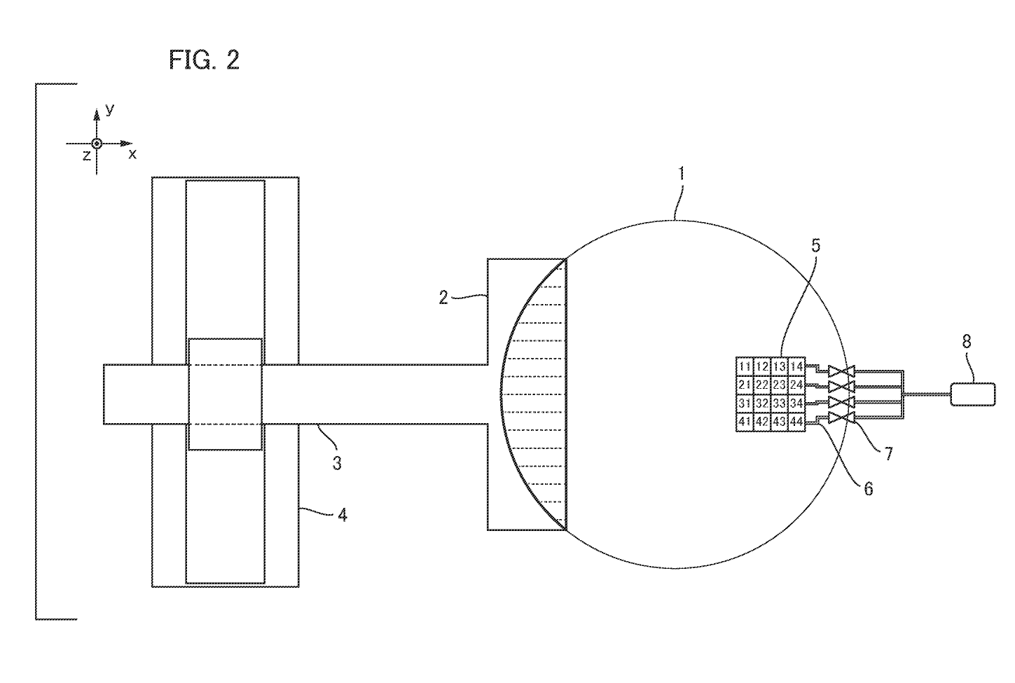

FIG. 2 is the top view of FIG. 1 showing the stage holding the substrate 1. FIG. 2 shows the chucking part 5 with its surface divided into 16 regions (4×4) having the numbers on them. Each of the divided regions is attached to vacuum pipes 6 and the electromagnetic valves 7 respectively, and can be controlled with its chucking strength by the chuck control unit 8. Although this example has the 16 divided regions, it is actually possible to be divided more.

The imprint process of the imprint apparatus in FIG. 1 is explained as follows. First, the template 9 is held on the imprint head 11 and the substrate 1 is held on the moving part 2. The substrate 1 held is moved to under a dispenser (not illustrated) by the x-axis and y-axis actuators 3 and 4 respectively. The dispenser jets resist on the substrate 1, which is solidified with UV exposure. The area to be imprinted and its surrounding areas are chucked by the chucking part 5. Just after this, the moving part 2 releases the substrate 1, or the x-axis and y-axis actuators 3 and 4 stop the servo control. These actions make the substrate 1 free from the x-axis and the y-axis actuators 3 and 4, and be held on the chucking part 5 in isolated. The alignment scope 10 measures a position shift between alignment marks on the template 9 and alignment marks on the substrate 1. The template 9 and the substrate 1 are aligned with their position by the x-axis and y-axis fine actuators 16 and 17 according to the measurement result. The template 9 is moved in the z direction and touches the resist on the substrate 1. This condition is kept until the resist spreads all spaces of the template patterns. After spreading enough, the imprint control unit 14 orders the ultraviolet irradiation mechanism 12 to expose UV to the resist via a reflection mirror 13. Then the resist solidifies. The imprint head 11 goes up in the z direction, having the template 9 separate from the resist. As a result, the resist gets the same pattern as the template. The resist is patterned on all the regions of the substrate by this way. Then the substrate is ejected.

Unlike the conventional technology in which the moving part and the chuck are integrated as one portion, the stage of the present invention is configured to have the moving part 2 and the chuck physically isolated as its feature. Because of this configuration, many tubes and related parts do not have to be mounted on the moving part 2. It means that the stage does not have to be bigger or heavier. This enables fast movement of the stage. Furthermore, because the moving part 2 just moves the substrate 1 roughly not aligning it precisely, the moving part can be configured with rough specification. In addition, because the chuck does not have to move, it can have many tubes and related parts without any problem.

During the separation, the chucking strength of each divided region can be controlled individually to the optimum by the chuck control unit 8. It decreases the separation defects. This chuck control can also be applied to the spread phase as well as the separation phase, which makes the resist spread faster.

As described above, according to this embodiment, it is possible to accomplish both decreasing separation defects and promoting fast movement of a stage for high throughput by dividing a holding surface into many divided regions and regulating their chucking strength individually.

### Second Embodiment

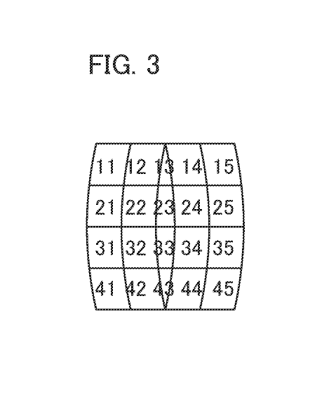

FIG. 3 is a sketch of the divided regions of the holding surface of the chuck according to the second embodiment. This is a holding surface of the chucking part 5 in FIGS. 1 and 2. The holding surface of the first embodiment is divided into square shapes, but the holding surface of the second embodiment is divided into shapes with its edges corresponding to the substrate edge.

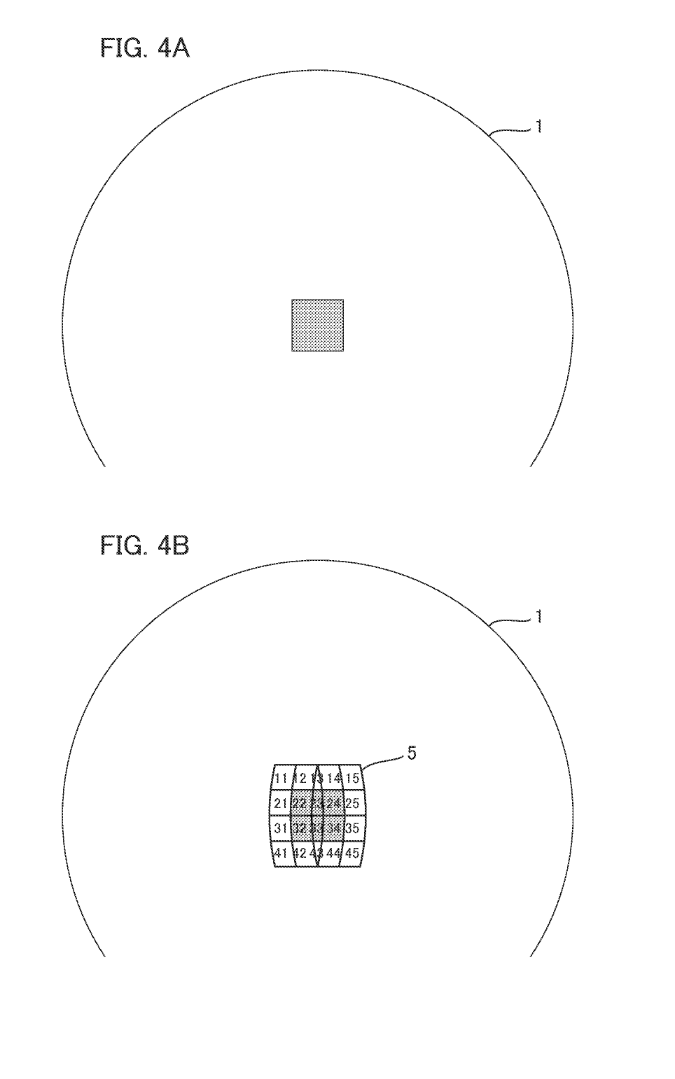

In the following sentences, it is explained that how the holding surface chucks a substrate in this embodiment. FIG. 4 illustrates the case in which an imprint process is performed in the vicinity of the center of the substrate 1. The shaded area of FIG. 4A indicates an imprint processing region on the substrate 1. FIG. 4B illustrates the chucking part 5 chucking the imprint processing region and its surrounding areas. The substrate 1 should be placed on the chucking part 5 with the center of the imprint processing region corresponded to the center of the chucking part 5. This helps proper balance and chucking. Further, if necessary, it is possible to set up optimum chucking condition by having different chucking strength depending on the area between the shaded regions 22, 23, 24, 32, 33, and the other regions. The stage with the chuck having the said holding surface also has the same effect as the first embodiment.

### Third Embodiment

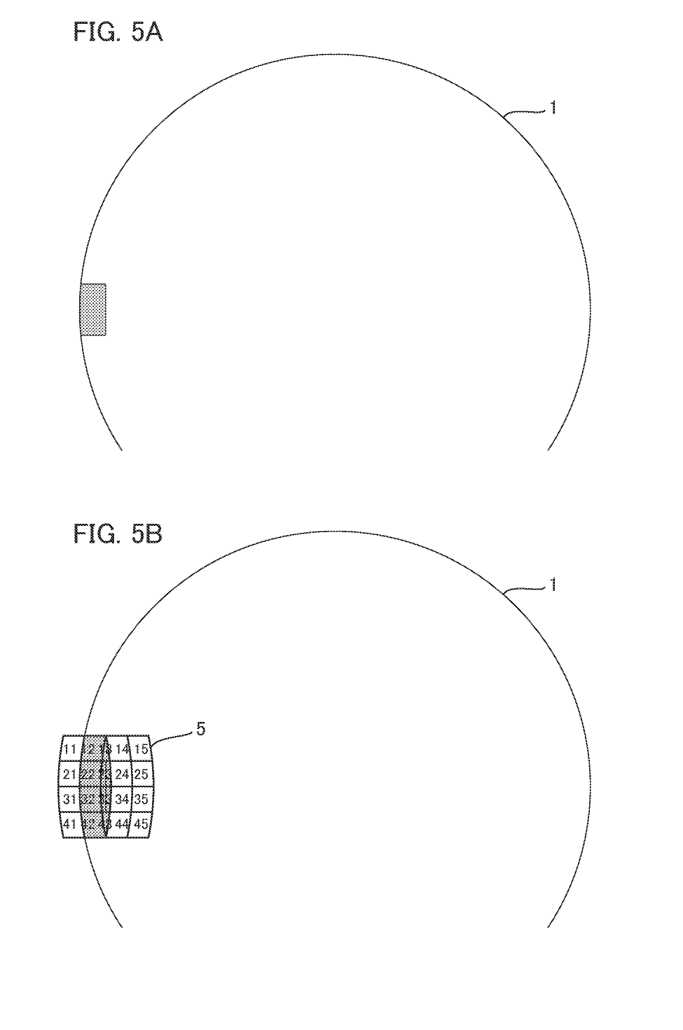

FIG. 5 illustrates the case in which an imprint process is performed on the left edge of the substrate 1. In FIG. 5A, the shaded area of the substrate 1 is to be imprinted. In FIG. 5B, the chucking part 5 is holding the area and its neighboring areas.

In manufacturing semiconductor devices, even small areas around the substrate edge shown in FIG. 5A are also processed to enhance its productivity, which are smaller than the common processed areas shown in FIG. 4A. Each shaded area in FIG. 5A contains several pieces of semiconductor chips which can be the products.

In the imprint process, pattern defects are likely generated around the edge. When the template separates from the substrate, the resist is pulled between the template and the substrate. When the pulling loses the balance, the pattern defects are generated. In FIG. 5A, the said imbalance would happen in the following situation. If all the attaching areas chuck the substrate, the right side of the processed region has larger holding strength than the left side, which causes the imbalance and results in tearing the pattern.

In the case of FIG. 5B, holding strength of regions 12, 13, 22, 23, 32, 33, 42, and 43 should be different from that of other regions to make the good balance and separation.

In this embodiment, since the divided holding regions have the edges which correspond the substrate edge, the chucking can be completed up to the very edge of the substrate. In the first embodiment, since the divided holding regions have square edges, the chucking cannot be done well at the very edge of the substrate. The regions on the substrate edge end up with vacuuming air from the gap. In this case, the said holding regions just beneath the substrate edge cannot be used for the chucking. The inner regions next to them are to be used instead. This makes the chucking balance worse. In this embodiment, chucking to the very edge enables the well-balanced chucking control. The stage with this type of holding surface has the same effect as the first and second embodiments.

### Fourth Embodiment

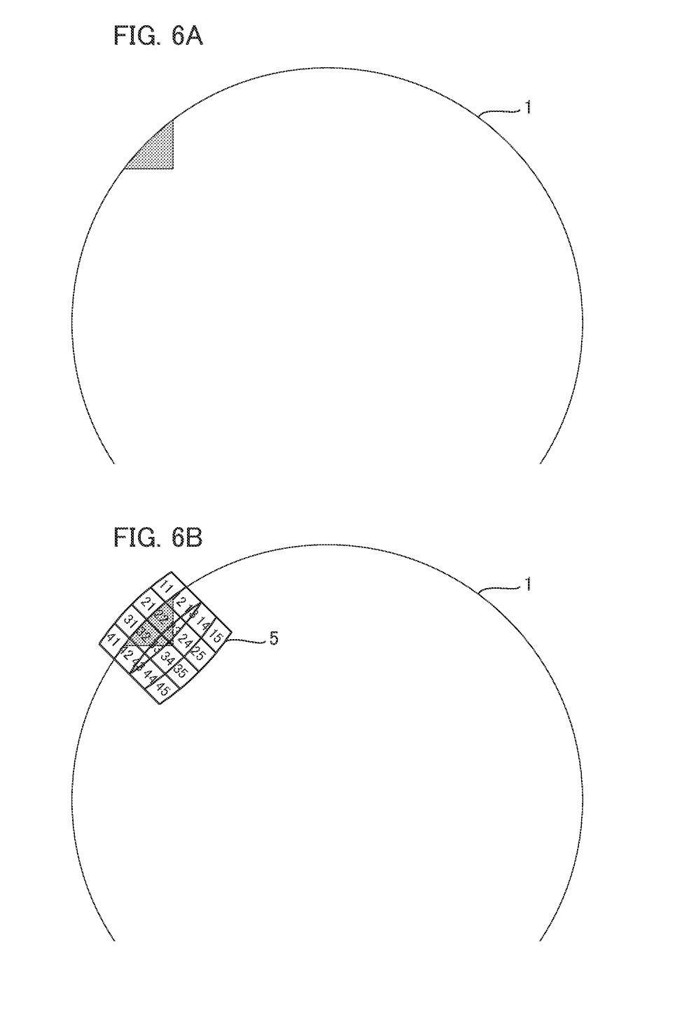

FIG. 6 illustrates the case in which an imprint process is performed on the upper left edge of the substrate 1. In FIG. 6A, the shaded area of the substrate 1 is to be imprinted. In FIG. 6B, the chucking part 5 is holding the area and its neighboring areas. The chucking part 5 is attached to an actuator which rotates around the z-axis perpendicular to the substrate. The actuator rotates to make the edges of the divided regions correspond to the substrate edge. This helps the divided regions chuck the substrate properly to its very edge. The stage with this type of holding surface has the same effect as the first, second, and third embodiments.

In the first to fourth embodiments, the present invention is applied to so-called imprint lithography. The imprint lithography transfers patterns on templates to substrates by pressing the templates to the resist on the substrates and solidifying the resist with light exposure. The present invention can also be applied to conventional optical lithography which transfers patterns on templates to substrates by projecting the patterns on the processed areas of the substrates with projection optics. And the vacuum chucking system in the said embodiments can also be replaced with other chucking methods such as electrostatic chucking system.

### (Article Manufacturing Method)

A method for manufacturing a device (semiconductor integrated circuit element, liquid display element, or the like) as an article may include a step of transferring (forming) a pattern on a substrate (wafer, glass plate, film-like substrate, or the like) using the lithography apparatus described above. Furthermore, the manufacturing method may include a step of etching the substrate on which a pattern has been formed. When other articles such as a patterned medium (storage medium), an optical element, or the like are manufactured, the manufacturing method may include another step of processing the substrate on which a pattern has been transferred (formed) instead of the etching step.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-247721 filed Dec. 8, 2014, which is hereby incorporated by reference herein in its entirety.

1. A stage apparatus comprising:
a movable stage configured to move while holding a substrate; and
a chuck configured to have divided holding regions so that the holding strength is controlled individually and some of the regions hold a part of the substrate,
wherein the movable stage and the chuck are configured to be physically isolated.

2. The stage apparatus according to claim 1, wherein the movable stage holds the substrate in a cantilever state.

3. The stage apparatus according to claim 1, wherein the chuck holds the substrate by vacuuming it.

4. The stage apparatus according to claim 1, wherein each of the divided holding regions has a shape that corresponds an outer circumference of the substrate.

5. The stage apparatus according to claim 1, comprising:
actuators configured to drive the holding unit on a plane parallel to the substrate.

6. The stage apparatus according to claim 1, comprising:
actuators configured to rotate the holding unit in the same rotation direction as the substrate.

7. A lithography apparatus for forming patterns of an original plate on a substrate, including a stage apparatus comprising:
a movable stage configured to move while holding a substrate; and
a chuck configured to have divided holding regions so that the holding strength is controlled individually and some of the regions hold a part of the substrate,
wherein the movable stage and the chuck are configured to be physically isolated.

8. The lithography apparatus according to claim 7, wherein the lithography apparatus is an imprint apparatus for forming patterns of the original plate on the substrate by curing an uncured resin in a state in which the uncured resin on the substrate and the original plate are in contact and peeling off the original plate from the cured resin.

9. A method of manufacturing an article, the method comprising steps of:
forming patterns of an original plate on a substrate using a lithography apparatus; and
processing the substrate on which the patterns are formed,
wherein the lithography apparatus includes a stage apparatus configured to hold the substrate,
wherein the stage apparatus includes:
a movable stage configured to move while holding the substrate; and
a chuck configured to have divided holding surfaces so that the holding strength is controlled individually and some of the regions hold a part of the substrate, and
wherein the movable stage and the chuck are configured to be physically isolated.
